(19) United States
(12) Patent Application Publication
(10) Pub. No.: US 2014/0374153 A1
(43) Pub. Date: Dec. 25, 2014

(54) PRINTED CIRCUIT BOARD AND METHOD FOR MANUFACTURING SAME

(71) Applicants: Zhen Ding Technology Co., Ltd., Tayuan (TW); FuKui Precision Component (Shenzhen) Co., Ltd., Shenzhen (CN)

(72) Inventors: YU-HSIEN LEE, New Taipei (TW); FU-WEI ZHONG, Shenzhen (CN); RUI-WU LIU, Shenzhen (CN)

(73) Assignees: ZHEN DING TECHNOLOGY CO., LTD., Tayuan (TW); FUKUI PRECISION COMPONENT (SHENZHEN) CO., LTD., Shenzhen (CN)

(21) Appl. No.: 14/149,831

(22) Filed: Jan. 8, 2014

(30) Foreign Application Priority Data
Jun. 21, 2013 (CN) 201310248714X

(51) Int. Cl. H05K 3/46; H05K 1/11

(52) U.S. Cl. CPC H05K 3/4623; H05K 1/115; H05K 3/4611
USPC 174/264; 156/280; 156/252

(57) ABSTRACT

A PCB includes at least three single layer circuit boards laminated together. The single layer circuit boards include two outer circuit boards and at least one inner circuit board. Each single layer circuit board includes a dielectric layer and a conductive layer on a surface of the dielectric layer. The dielectric layer is selected from a material of thermoplastic resin. Each single layer circuit board defines at least one blind hole passing through the dielectric layer and is ended at the conductive layer. Each blind hole is filled with a filler material electrically connected to the conductive layer. The conductive layer of the at least one inner circuit board forms a first conductive circuit pattern, and the conductive layers of the outer circuit boards each form a second conductive circuit pattern. The second conductive circuit pattern is electrically connected to the first conductive circuit pattern by the filler material.

### BACKGROUND

1. Technical Field

The present disclosure relates to technologies for manufacturing printed circuit boards (PCBs), and particularly to a multi-layer PCB and a method for manufacturing the multi-layer PCB.

2. Description of Related Art

Multi-layer PCBs include a number of laminated layers. A lamination process is employed for laminating the layers together. However, if the PCB has a large number of layers to be laminated together, the lamination process should be repeated many times, it is bothersome and may increase a cost of the PCB.

Therefore, what is needed is a PCB and a method for manufacturing the PCB addressing the limitations described.

### BRIEF DESCRIPTION OF THE DRAWING

The components of the drawing are not necessarily drawn to scale, the emphasis instead being placed upon clearly illustrating the principles of the embodiments of the present disclosure.

FIGS. 1-10 are schematic views of a method for making a PCB, according to an exemplary embodiment of the present disclosure.

### DETAILED DESCRIPTION

The method includes the following steps.

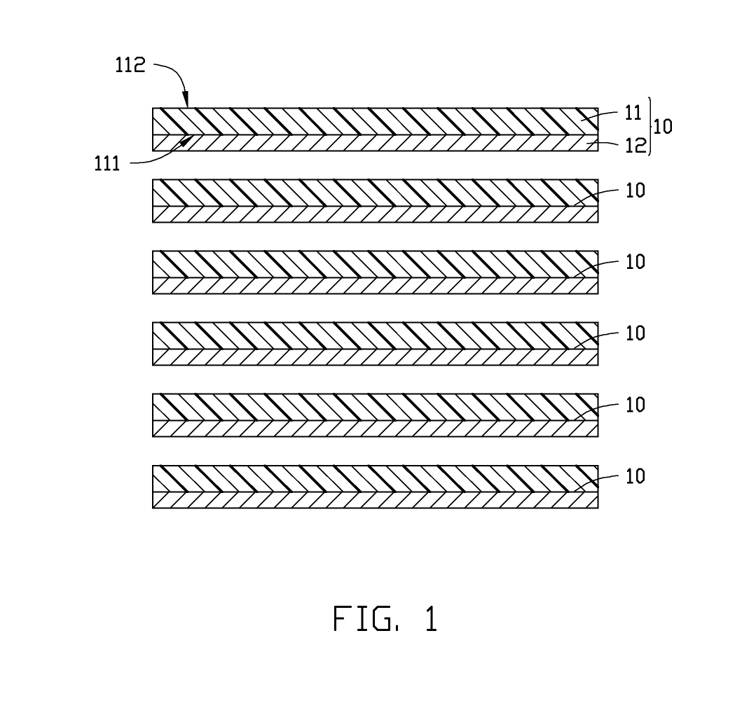

FIG. 1 shows a number of substrates 10. Each substrate 10 includes a dielectric layer 11 and a conductive layer 12 formed on the dielectric layer 11. The dielectric layer 11 includes a first surface 111 and a second surface 112 opposite to the first surface 111. The dielectric layer 11 is made from thermoplastic resin. In this embodiment, the material of the dielectric layer 11 is thermotropic liquid crystalline polymer (LCP), which has high coefficient of thermal expansion, low water absorption rate, high heat resisting property, and halogen free flame retardant property. The conductive layer 12 is formed on the first surface 111 of the dielectric layer 11. In this embodiment, a material of the conductive layer 12 is copper.

The number of the substrate 10 is at least three and equals to a number of the layers of a final multi-layer PCB manufactured by the method. In this embodiment, the number of the substrate 10 is six.

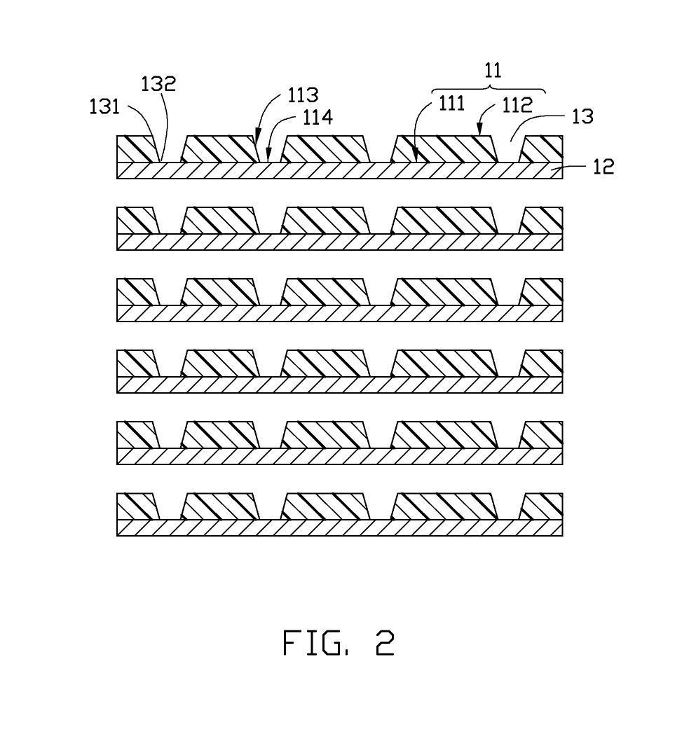

FIG. 2 shows that at least one blind hole 13 is formed in each substrate 10. In this embodiment, the blind hole 13 is formed in the substrate 10 by a laser ablation process. Each blind hole 13 passes through a corresponding dielectric layer 11 from the first surface 111 to the second surface 112 and is ended at the second surface 112. Each blind hole 13 forms an inner side surface 113 in the dielectric layer 11, connected to the first surface 111 and the second surface 112. A portion of the conductive layer 12 is exposed by each blind hole 13, the exposed portion of the conductive layer 12 forms a bottom surface 114 of the blind hole 13. The blind hole 13 includes an open end 131 in the first surface 111. The blind hole 13 tapers from the first surface 111 to the second surface 112, thus a shape of a cross section of the blind hole 13 is substantial a trapezium.

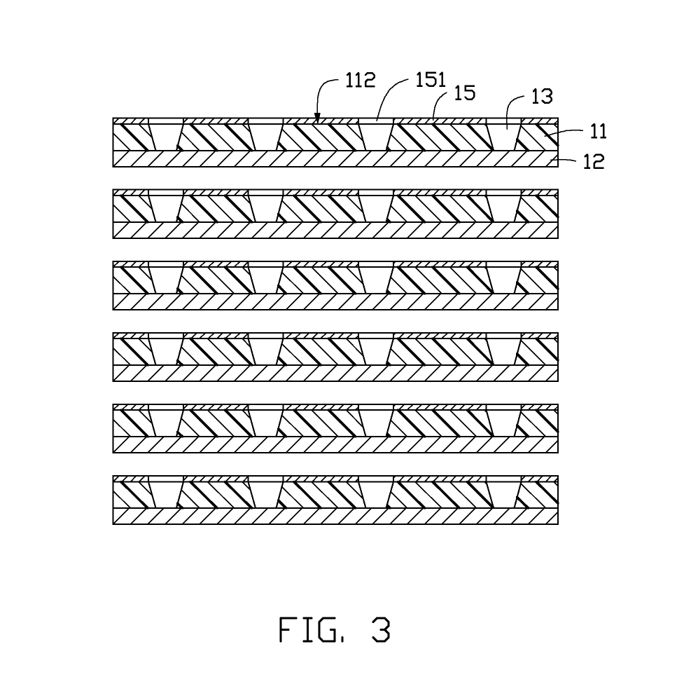

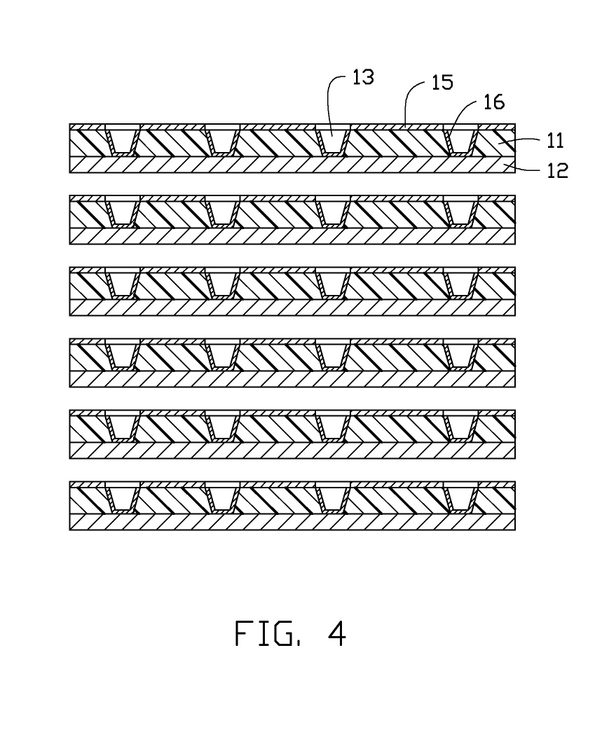

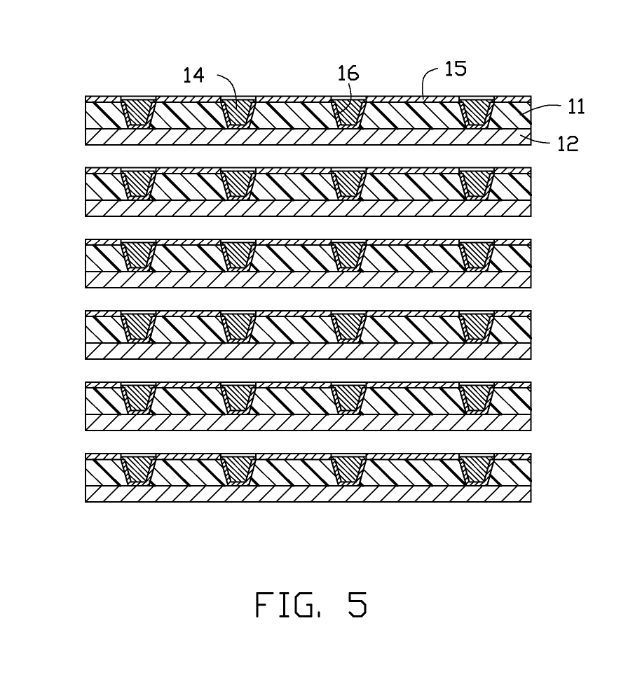

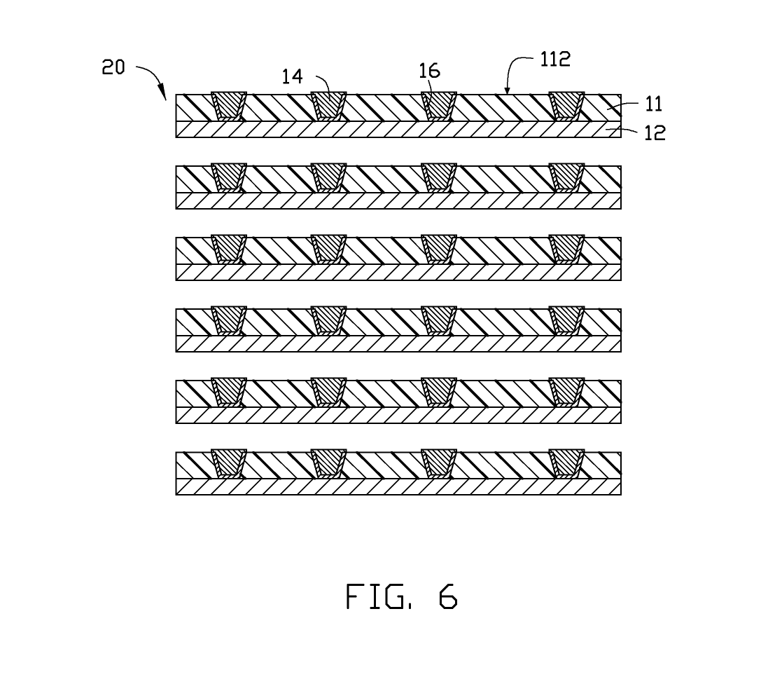

FIGS. 3-6 show that a filler material 14 is filled in each blind hole 13. The detailed process of the third step includes the following steps.

First, a photo-induced etchant layer 15 is formed on the second surface 112 of the dielectric layer 11. Second, at least one opening 151 is formed in the photo-induced etchant layer 15 corresponding to an opening end 131 of the blind hole 13, a size of the opening 151 is slightly larger than that of the opening end 131 of the blind hole 13, thus the bind hole 13 is exposed by the opening 151. The opening 151 is formed by a photolithography technology. Third, a conductive film 16 is formed on the inner side surface 113 and the bottom surface 114 of the blind hole 13. The conductive film 16 can be formed by a chemical plating process, a shadow process or a black oxide process. In this embodiment, the conductive film 16 is formed by the chemical plating process. Fourth, the filler material 14 is filled in the blind hole 13. The filler material 14 is electrically connected to the conductive layer 12 by the conductive film 16. In this embodiment, the filler material 14 is filled in the blind hole 13 by a one-side plating process. The filler material 14 slightly protrudes from the second surface 112 of the dielectric layer 11. In detail, a protruding distance of the filler material 14 is 1-3 micrometers. Finally, the photo-induced etchant layer 15 is removed, thus a number of single layer circuit boards 20 are formed.

It is understood that, the conductive film 16 can be eliminated, and the filler material 14 can be directly filled in the blind hole 13 without the conductive film 16.

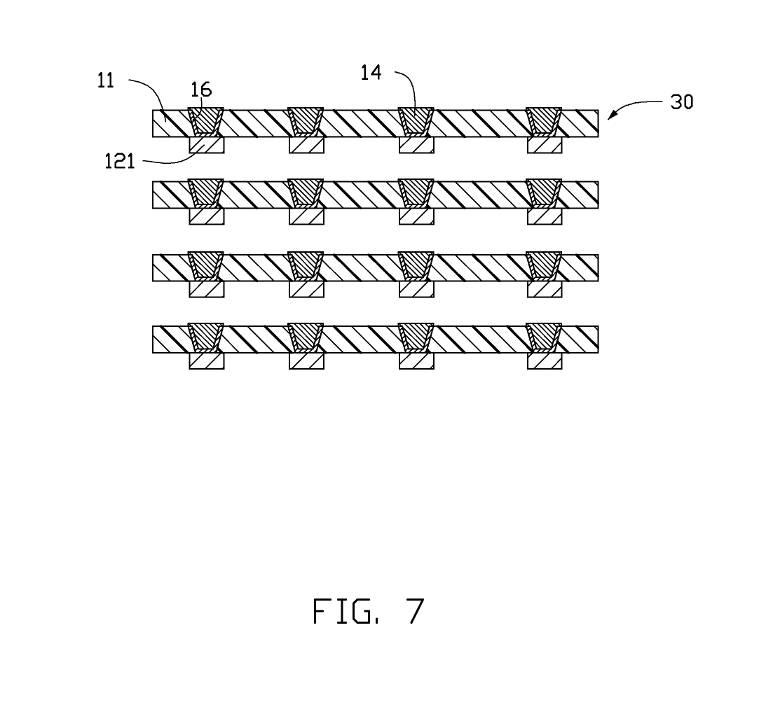

FIG. 7 shows that some of the single layer circuit boards 20 each are coated with a first conductive circuit pattern 121, with two of the single layer circuit boards 20 without being coated with the first conductive circuit pattern 121. The single layer circuit boards 20 with the first conductive circuit pattern 121 serve as a number of inner circuit boards 30. In this embodiment, the first conductive circuit pattern 121 is formed by a photolithography technology.

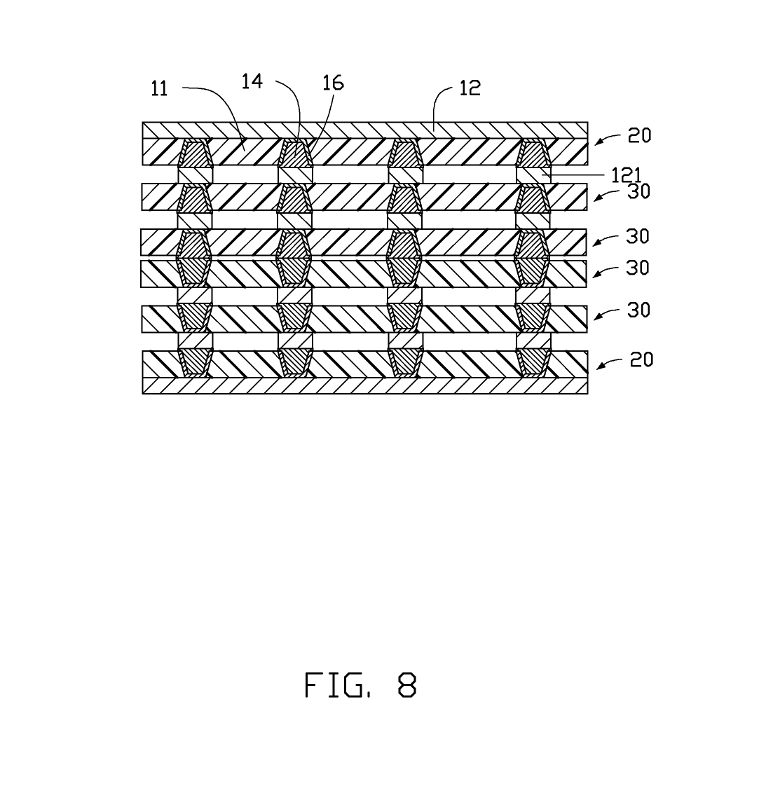

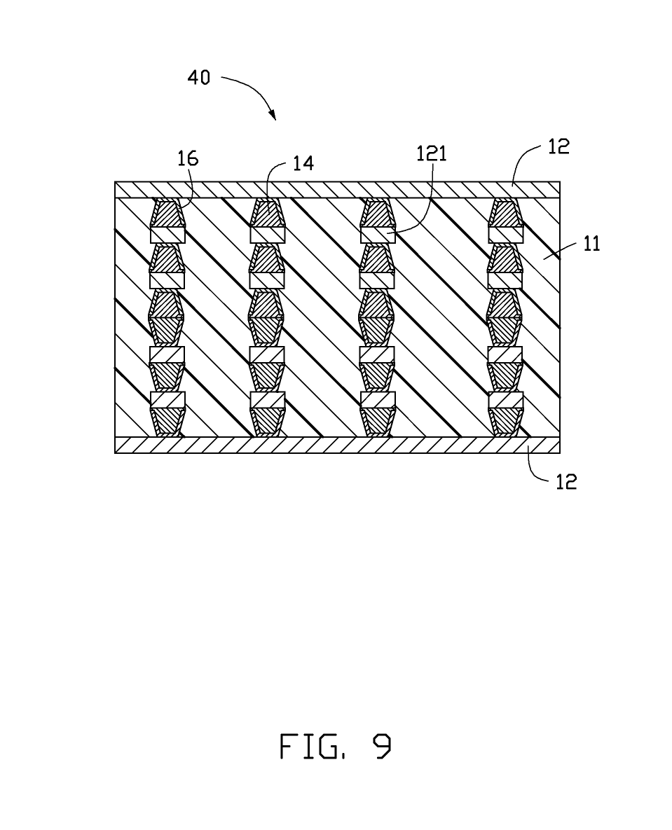

FIGS. 8-9 show that the single layer circuit boards 20 are laminated together to form a multi-layer circuit board 40. The single layer circuit boards 20 with the first conductive circuit pattern 121 (the inner circuit boards 30) are inner layers of the multi-layer circuit board 40, and the two single layer circuit boards 20 without the first conductive circuit pattern 121 are opposite outer layers of the multi-layer circuit board 40. In this embodiment, the single layer circuit boards 20 are laminated together by a heat pressing process.

In detail, adjacent first conductive circuit patterns 121 are spaced by the filler material 14 and electrically connected to each other by the filler material 14. Adjacent first conductive circuit pattern 121 and conductive layer 12 are also spaced by the filler material 14 and electrically connected to each other by the filler material 14. After the heat pressing process, the dielectric layers 11 of the single layer circuit boards 20 are melted and are solidified to form an integral dielectric layer.

In this embodiment, two of the inner circuit boards 30 are laminated together with the second surfaces 112 facing each other, thus the filler materials 14 of the two inner circuit boards 30 are directly contact each other. Because the filler materials 14 slightly protrude from the corresponding second surfaces 112, an excellent contact between the filler materials 14 during the heat pressing process is ensured.

In this embodiment, the first surfaces 111 of the inner circuit boards 30 adjacent to the outer single layer circuit boards 20 respectively face toward the second surfaces 112 of the corresponding outmost single layer circuit boards 20. Alternatively, the second surfaces 111 of the inner circuit boards 30 can be respectively contacted with the second surfaces 111 of the corresponding outmost single circuit boards 20.

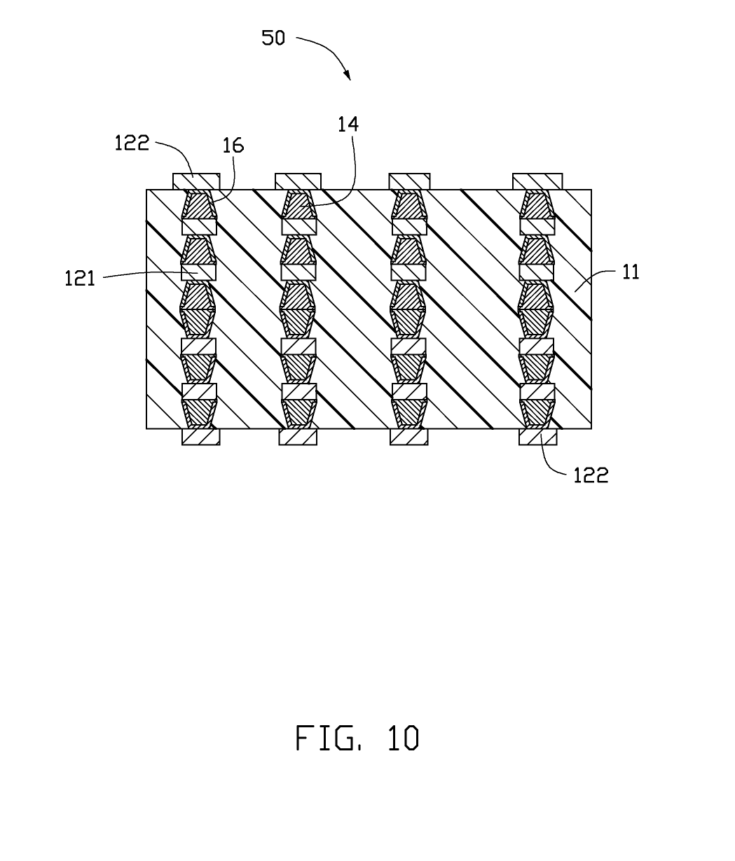

Referring to FIG. 10, a second conductive circuit pattern 122 is formed on each outmost single circuit board 20 to form a multi-layer PCB 50. The second conductive circuit pattern 122 is electrically connected to the filler material 14 by the conductive film 16. In this embodiment, the second conductive circuit pattern 122 is formed by a photolithography technology.

Finally, a solder resist layer (not shown) can be formed on each outmost single circuit board 20 covering the corresponding second conductive circuit pattern 122.

The above-described method can be applied to manufacture a rigid PCB, a flexible PCB (FPCB), or a rigid-flex compound PCB.

The method for manufacturing the multi-layer PCB 50 employs thermoplastic resin as the dielectric layer 11, the substrates 10 can be laminated together by one time of heat pressing process, therefore, a manufacturing efficiency of the multi-layer PCB 50 is increased, and a cost of the multi-layer PCB 50 is decreased.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being exemplary embodiments of the disclosure.

What is claimed is:

1. A method for making a PCB, comprising:
providing at least three single layer circuit boards, each single layer circuit board comprising a dielectric layer and a conductive layer formed on a surface of the dielectric layer, the dielectric layer being selected from a material of thermoplastic resin, each single layer circuit board defining at least one blind hole, each blind hole passing through the dielectric layer and being ended at the conductive layer, each blind hole being filled with a filler material, the filler material being electrically connected to the conductive layer, the single layer circuit boards comprising two outer circuit boards and at least one inner circuit board;
forming a first conductive circuit pattern on the conductive layer of the at least one inner circuit board;
laminating the at least three single layer circuit boards together by a heat pressing process, the at least one inner circuit board being sandwiched between the outer circuit boards, the conductive layers of the outer circuit boards being electrically connected to the first conductive circuit pattern by the filler material; and
forming a second conductive circuit pattern on each of the outer circuit boards.

2. The method of claim 1, wherein each single layer circuit boards is manufactured by a method comprising:
providing a substrate, the substrate comprising the dielectric layer and the conductive layer;
forming the at least one blind hole in the substrate; and
filling the filler material into the at least one blind hole.

3. The method of claim 2, wherein the at least one blind hole comprises an inner side surface and a bottom surface formed by a portion of the conductive layer exposed by the at least one blind hole, a conductive film is coated on the inner side surface and the bottom surface before the filler material is filled into the blind hole, the filler material is electrically connected to the conductive layer by the conductive film.

4. The method of claim 3, wherein the conductive film is coated on the inner side surface and the bottom surface by chemical plating process, shadow process or black oxide process.

5. The method of claim 2, wherein the at least one blind hole is formed by a laser ablation process.

6. The method of claim 2, wherein the least one blind hole tapers from a side surface of the substrate away from the conductive layer to a side surface of the substrate adjacent to the conductive layer.

7. The method of claim 6, wherein the filler material slightly protrudes from the side of the surface of the substrate away from the conductive layer.

8. The method of claim 7, wherein a protruding distance of the filler material is in a range of 1-3 micrometers.

9. The method of claim 6, wherein the filler material is filled into the at least one blind hole by a one-side plating process.

10. The method of claim 2, wherein in laminating the at least three single layer circuit boards, if the number of the at least one inner circuit board is more than two, two of the inner circuit boards are laminated together with the surfaces away from the corresponding first conductive circuit patterns facing toward each other, and the filler materials of the two inner circuit boards directly contact with each other.

11. The method of claim 10, wherein one of the outer circuit boards and an inner circuit board adjacent to the outer circuit board are laminated together with the surface of the outer circuit board away from the corresponding conductive layer facing toward the first conductive circuit pattern of the inner circuit board.

12. The method of claim 1, wherein the first conductive and the second conductive patterns are respectively formed by a photolithography process.

13. A PCB, comprising:
at least three single layer circuit boards laminated together, the at least three single layer circuit boards comprising two outer circuit boards and at least one inner circuit board sandwiched between the outer circuit boards, each single layer circuit board comprising:
a dielectric layer, the dielectric layer being selected from a material of thermoplastic resin; and
a conductive layer formed on a surface of the dielectric layer;
wherein each single layer circuit board defines at least one blind hole, each blind hole passes through the dielectric layer and is ended at the conductive layer, each blind hole is filled with a filler material, the filler material is electrically connected to the conductive layer, the conductive layer of the at least one inner circuit board forms a first conductive circuit pattern, the conductive layers of the outer circuit boards respectively each form a second conductive circuit pattern, the second conductive circuit pattern is electrically connected to the first conductive circuit pattern by the filler material.

14. The PCB of claim 13, wherein each blind hole comprises an inner side surface and a bottom surface formed by a portion of the conductive layer exposed by the blind hole, a conductive film is coated on the inner side surface and the bottom surface, the filler material is electrically connected to the conductive layer by the conductive film.

15. The PCB of claim 13, wherein each blind hole tapers from a side surface of the dielectric layer away from the conductive layer to a side surface of the dielectric layer adjacent to the conductive layer.

16. The PCB of claim 15, wherein the filler material slightly protrudes from the side of the surface of the dielectric layer away from the conductive layer.

17. The PCB of claim 16, wherein a protruding distance of the filler material is in a range of 1-3 micrometers.
